(19) United States
(12) Patent Application Publication
(10) Pub. No.: US 2026/0018528 A1
(43) Pub. Date: Jan. 15, 2026

(54) PACKAGE STRUCTURE AND MANUFACTURING METHOD THEREOF

(71) Applicant: Chung W. Ho, Taipei City (TW)

(72) Inventor: Chung W. Ho, Taipei City (TW)

(21) Appl. No.: 18/803,975

(22) Filed: Aug. 14, 2024

(30) Foreign Application Priority Data
Jul. 9, 2024 (TW) 113125651

(51) Int. Cl. H01L 23/538; H01L 23/00; H01L 23/18; H01L 23/373; H01L 23/498; H01L 25/065; H01L 25/16

(52) U.S. Cl. CPC H01L 23/5389; H01L 23/18; H01L 23/373; H01L 23/49822; H01L 23/49833; H01L 23/49838; H01L 23/5385; H01L 23/5386; H01L 23/562; H01L 24/24; H01L 25/0655; H01L 25/16; H01L 2224/24225; H01L 2924/19041; H01L 2924/19101

(57) ABSTRACT

A package structure includes an embedded component circuit structure layer, a signal interconnection structure layer, a power structure layer, and an electronic component layer. The embedded component circuit structure layer includes at least one embedded component and has a first surface and a second surface opposite to each other. The signal interconnection structure layer is disposed on the first surface and is electrically connected to the embedded component circuit structure layer. The power structure layer is disposed on and electrically connected to the signal interconnection structure layer. The electronic component layer includes a plurality of electronic components, is disposed on the second surface, and is electrically connected to the embedded component circuit structure layer. A coefficient of thermal expansion of the signal interconnection structure layer is higher than a coefficient of thermal expansion of the electronic component layer and a coefficient of thermal expansion of the power structure layer.

### CROSS-REFERENCE TO RELATED APPLICATION

This application claims the priority benefit of Taiwan application serial no. 113125651, filed on Jul. 9, 2024. The entirety of the above-mentioned patent application is hereby incorporated by reference herein and made a part of specification.

### BACKGROUND

### Technical Field

The disclosure relates to a semiconductor structure and a manufacturing method thereof, and in particular, to a package structure and a manufacturing method thereof.

### Description of Related Art

One key to heterogeneous chiplet integration lies in the electrical connection between the adjacent chips. At present, Intel uses the embedded multi-die interconnect bridge (EMIB) to connect the adjacent chips, so as to achieve partial (or local) high-density interconnection. However, a problem encountered by the abovementioned technology is that the bridge is required to be embedded in the organic core interconnect substrate toward the end of the substrate construction. Therefore, in addition to the issue of whether the surface is flat enough for subsequent flip-chip package operations, there is also the issue of the high costs of the organic core interconnect substrate.

### SUMMARY

The disclosure provides a package structure and a manufacturing method thereof capable of solving the problems found in the related art, providing lower costs, and improved structural stability.

The disclosure provides a package structure including an embedded component circuit structure layer, a signal interconnection structure layer, a power structure layer, and an electronic component layer. The embedded component circuit structure layer includes at least one embedded component and has a first surface and a second surface opposite to each other. The signal interconnection structure layer is disposed on the first surface of the embedded component circuit structure layer and is electrically connected to the embedded component circuit structure layer. The power structure layer is disposed on and electrically connected to the signal interconnection structure layer. The electronic component layer includes a plurality of electronic components, is disposed on the second surface of the embedded component circuit structure layer, and is electrically connected to the embedded component circuit structure layer. A coefficient of thermal expansion of the signal interconnection structure layer is higher than a coefficient of thermal expansion of the electronic component layer and a coefficient of thermal expansion of the power structure layer, and the coefficients of thermal expansion of the latter two are similar.

In an embodiment of the disclosure, the embedded component circuit structure layer includes a plurality of metal pillars, a dielectric layer, a plurality of conductive vias, and a patterned circuit layer. The dielectric layer has a first surface and a second surface. The dielectric layer covers the metal pillars and the at least one embedded component. The second surface of the dielectric layer is aligned with at least one active surface of the at least one embedded component and a top surface of each of the metal pillars. The conductive vias extend from the first surface of the dielectric layer and are connected to the metal pillars. The patterned circuit layer is disposed on the first surface of the dielectric layer and is electrically connected to the conductive vias.

In an embodiment of the disclosure, a thickness of the dielectric layer is between 75 micrometers and 300 micrometers. A material of the dielectric layer includes an epoxy molding compound or an ajinomoto build-up film (ABF).

In an embodiment of the disclosure, the signal interconnection structure layer includes a plurality of dielectric layers, a plurality of patterned circuit layers, and a plurality of conductive blind holes. The dielectric layers and the patterned circuit layers are arranged in an alternating manner, and the conductive blind holes are electrically connected to two adjacent patterned circuit layers.

In an embodiment of the disclosure, each of the power structure layer is a power plane without traces but contains one or a plurality of different power segments on a same plane and has a plurality of copper layers, a plurality of dielectric layers, a plurality of vias, and a solder-mask layer. The vias penetrate the dielectric layers and are electrically connected to the signal interconnection structure layer.

In an embodiment of the disclosure, the power structure layer further includes embedded deep trench capacitors (DTC) and integrated voltage regulators (IVR), and these two types of chips are disposed in at least one of the dielectric layers.

In an embodiment of the disclosure, the electronic components include a co-packaged optics (CPO), at least one artificial intelligence super chip, at least one passive component, or a combination of the foregoing.

In an embodiment of the disclosure, the at least one embedded component includes an embedded multi-die interconnect bridge (EMIB) chip.

In an embodiment of the disclosure, the package structure further includes a stabilizing ring disposed on the second surface of the embedded component circuit structure layer and surrounding the electronic components.

The disclosure further provides a manufacturing method of a package structure, and the method includes the following steps. A carrier is provided. The carrier includes a base, a stainless steel layer, and a metal layer. The stainless steel layer is formed on the base and conformally covers the base, and the metal layer is formed on the stainless steel layer and conformally covers the stainless steel layer. An embedded component circuit structure layer is formed on the carrier. The embedded component circuit structure layer includes at least one embedded component and an insulating layer. An active surface of the at least one embedded component contacts the carrier. A signal interconnection structure layer is formed on a first surface of the embedded component circuit structure layer. The signal interconnection structure layer and the embedded component circuit structure layer are electrically connected. A power structure layer is formed on the signal interconnection structure layer. The power structure layer and the signal interconnection structure layer are electrically connected. The carrier is removed, and the active surface of the at least one embedded component and a second surface of the embedded component circuit structure layer are exposed. An electronic component layer including a plurality of electronic components are arranged on the second surface of the embedded component circuit structure layer. The electronic components and the embedded component circuit structure layer are electrically connected. The coefficient of thermal expansion of the signal interconnection structure layer is higher than the coefficient of thermal expansion of the electronic component layer and the coefficient of thermal expansion of the power structure layer.

To sum up, in the package structure of the disclosure, the coefficient of thermal expansion of the signal interconnection structure layer located between the embedded component circuit structure layer and the power structure layer is higher than the coefficient of thermal expansion of the electronic component layer and the coefficient of thermal expansion of the power structure layer, and the coefficients of thermal expansion of the latter two are similar. In this way, a stable balance effect is kept during temperature changes and the package structure warpage is effectively reduced, so the structural stability of the package structure of the disclosure is improved. In addition, compared to the related art in which an organic core interconnect substrate embedded with an embedded multi-die interconnect bridge chip is used, in the disclosure, in the manufacturing of the coreless embedded component circuit structure layer, the signal interconnection structure layer, and the power structure layer, the total substrate thickness is reduced and the production costs are effectively reduced.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1H are cross-sectional schematic views of a manufacturing method of a package structure according to an embodiment of the disclosure.

### DESCRIPTION OF THE EMBODIMENTS

The embodiments of the disclosure can be understood together with the drawings, and the drawings of the disclosure are also considered as part of the disclosure. It should be understood that the drawings of the disclosure are not drawn to scale. In fact, the dimensions of the components may be arbitrarily enlarged or reduced to clearly illustrate the features of the disclosure.

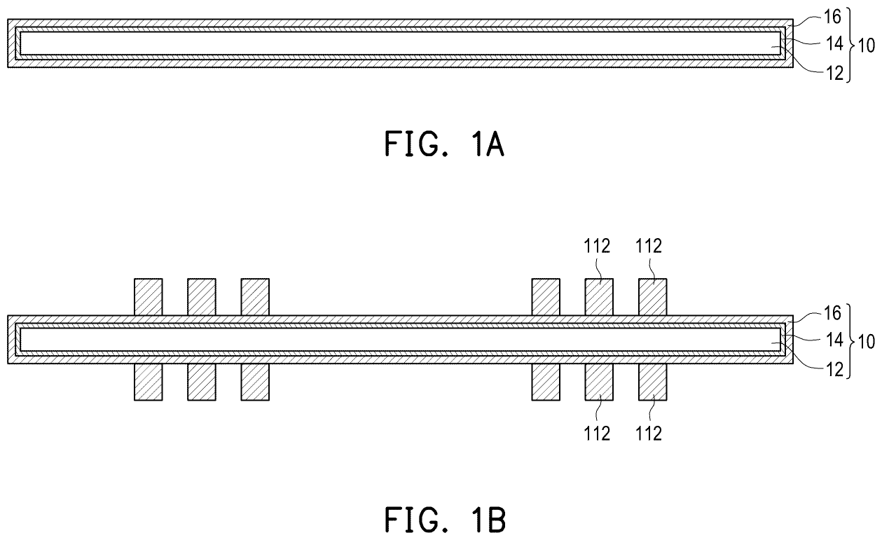

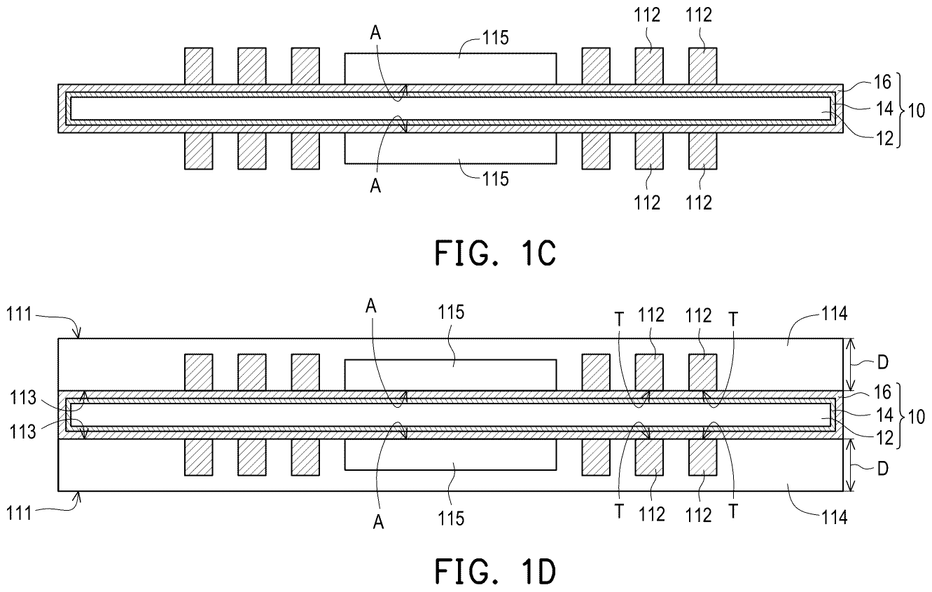

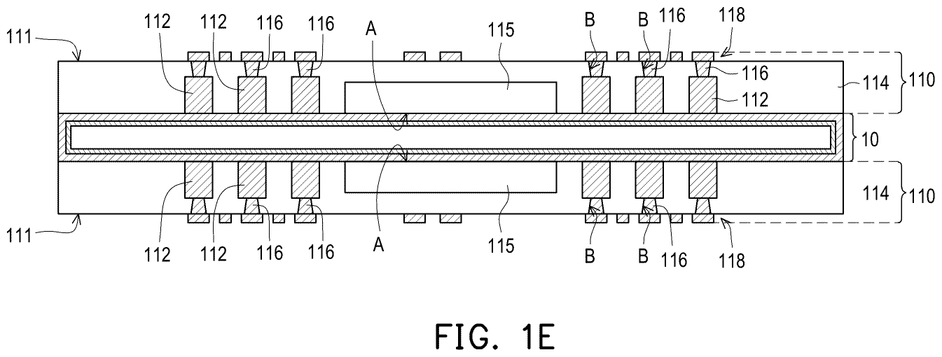

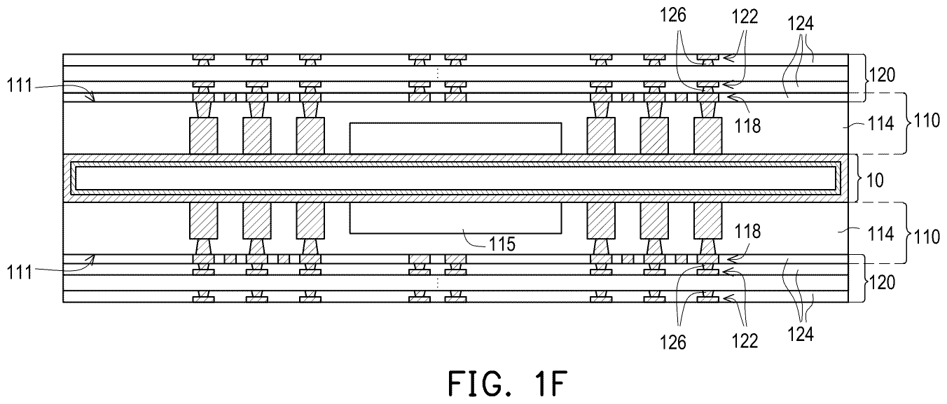

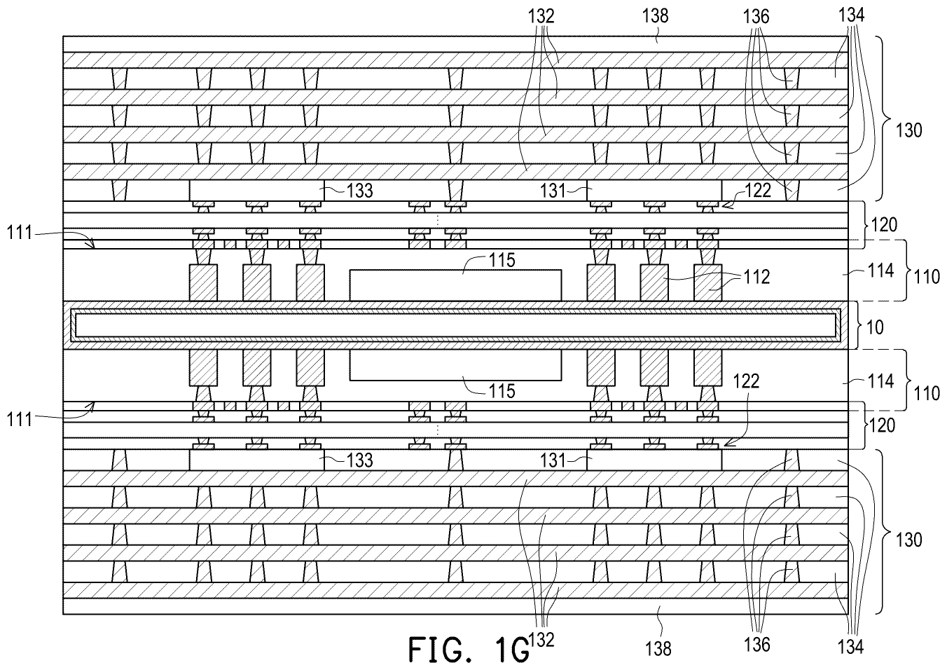

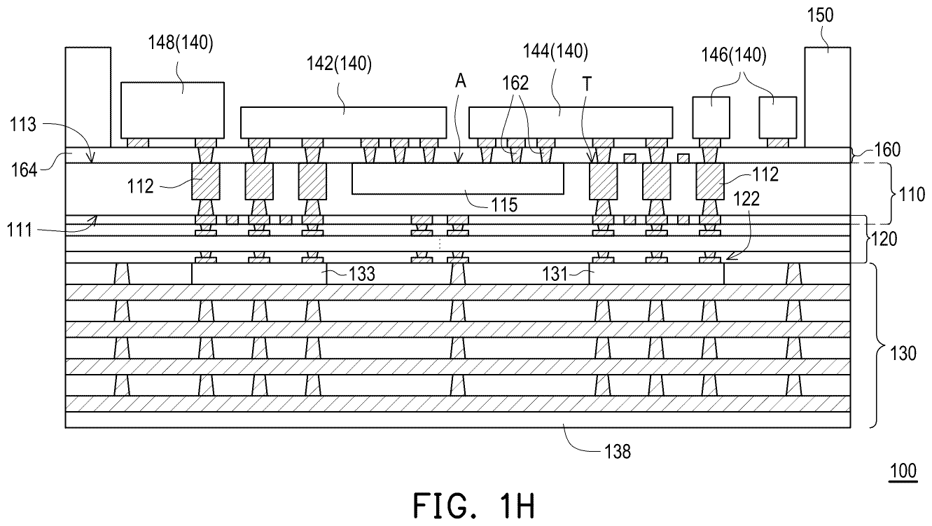

FIG. 1A to FIG. 1H are cross-sectional schematic views of a manufacturing method of a package structure according to an embodiment of the disclosure. It should be noted that the following is an example of a double-sided process that can be used to increase production capacity and structural strength. However, in other embodiments, a single-sided process may be adopted according to needs, which still falls within the scope of protection of the disclosure.

Regarding a manufacturing method of a package structure provided by this embodiment, first, with reference to FIG. 1A, a carrier 10 is provided. The carrier 10 includes a base 12, a stainless steel layer 14, and a metal layer 16. The stainless steel layer 14 is formed on the base 12 and conformally covers the base 12. The metal layer 16 is formed on the stainless steel layer 14 and conformally covers the stainless steel layer 14. Herein, the base 12 may be, for example, a core substrate composed of a sheet-shaped fiberglass resin base and copper foils disposed on opposite sides of the sheet-shaped fiberglass resin base, and may be treated as a hard board, but the disclosure is not limited thereto.

Next, with reference to FIG. 1B, the metal layer 16 is used as a seed layer, and a metal material layer is electroplated to form a plurality of metal pillars 112 separated from one another. In an embodiment, each metal pillar 112 has a height of 70 micrometers, for example, a diameter of 70 micrometers, for example, and a pitch of 90 micrometers, for example, but the disclosure is not limited thereto.

Next, with reference to FIG. 1C, at least one embedded component (two embedded components 115 are schematically shown) is attached to the metal layer 16, where active surfaces A of the embedded components 115 contact the metal layer 16 of the carrier 10, and the metal pillars 112 surround the embedded components 115. In an embodiment, the embedded components 115 are, for example, embedded multi-die interconnect bridge (EMIB) chips, but the disclosure is not limited thereto.

Next, with reference to FIG. 1D, a dielectric layer 114 is formed to cover the metal pillars 112 and the embedded components 115. The dielectric layer 114 has a first surface 111 and a second surface 113. Further, the second surface 113 of the dielectric layer 114 is aligned with the active surfaces A of the embedded components 115 and a top surface T of each of the metal pillars 112. In an embodiment, a thickness D of the dielectric layer 114 is between 75 micrometers and 300 micrometers, and the dielectric layer 114 may be treated as a flat layer. In an embodiment, a material of the dielectric layer 114 is, for example, an epoxy molding compound or an ajinomoto build-up film (ABF), but the disclosure is not limited thereto.

Next, with reference to FIG. 1E, a laser process, such as laser drilling, is performed on the dielectric layer 114 to form a plurality of blind holes B on the first surface 111 of the dielectric layer 114, where the blind holes B extend from the first surface 111 to the metal pillars 112. After that, the metal material layer is electroplated in the blind holes B and on the first surface 111 of the dielectric layer 114 to form conductive vias 116 structurally and electrically connected to the metal pillars 112 and a patterned circuit layer 118 located on the first surface 111 of the dielectric layer 114 and electrically connected to the conductive vias 116. At this point, the embedded component circuit structure layer 110 is formed on the carrier 10, where the embedded component circuit structure layer 110 includes the embedded components 115, and the active surfaces A of the embedded components 115 contact the carrier 10.

Next, with reference to FIG. 1F, a signal interconnection structure layer 120 is formed on the first surface 111 of the embedded component circuit structure layer 110, where the signal interconnection structure layer 120 and the embedded component circuit structure layer 110 are electrically connected. In an embodiment, the signal interconnection structure layer 120 includes a plurality of patterned circuit layers 122, a plurality of dielectric layers 124, and a plurality of conductive blind holes 126. The dielectric layers 124 and the patterned circuit layers 122 are arranged in an alternating manner (FIG. 1F, middle layers of the signal interconnection structure layer 120 are omitted, and the layers are connected by the conductive blind holes 126). Further, the dielectric layers 124 cover the first surface 111 of the embedded component circuit structure layer 110 and the patterned circuit layer 118, and the conductive blind holes 126 are electrically connected to two adjacent patterned circuit layers 122. In an embodiment, a material of each dielectric layer 124 is, for example, polyimide (PI), an ajinomoto build-up film (ABF), or benzocyclobutene (BCB), but the disclosure is not limited thereto. Materials of the patterned circuit layers 122 and the conductive blind holes 126 may be copper, for example, but the disclosure is not limited thereto. In an embodiment, the signal interconnection structure layer 120 may have nine layers of patterned circuit layers 122, where a line width/line spacing between the patterned circuit layers 122 is, for example, 8 micrometers, and a thickness of each patterned circuit layer 122 is, for example, 12 micrometers, but the disclosure is not limited thereto.

Next, with reference to FIG. 1G, a power structure layer 130 is formed on the signal interconnection structure layer 120, where the power structure layer 130 and the signal interconnection structure layer 120 are electrically connected. In an embodiment, each of the power structure layer 130 is a power plane without traces but contains one or a plurality of different power segments on a same plane and has a plurality of copper layers 132, a plurality of dielectric layers 134, a plurality of vias 136, and a solder-mask layer 138. The vias 136 penetrate the dielectric layers 134 and are electrically connected to the signal interconnection structure layer 120 to achieve power transmission. In an embodiment, provide a dielectric adhesive layer where a matrix of through hole is filled with conductive paste after being perforated by laser, the dielectric layer is used to attach the power structure layer 130 to the signal interconnection structure layer 120 by heat and pressure.

In an embodiment, a material of each dielectric layer 134 is, for example, prepreg (PP) or other materials with a low coefficient of thermal expansion (CTE). Herein, the low coefficient of thermal expansion is, for example, a coefficient of thermal expansion between 1 ppm/K and 3 ppm/K, but the disclosure is not limited thereto. A material of each via 136 is, for example, copper, but the disclosure is not limited thereto. Preferably, a peripheral surface of the signal interconnection structure layer 120 may be aligned with a peripheral surface of the power structure layer 130. That is, in this embodiment, a size of the power structure layer 130 is the same as a size of the signal interconnection structure layer 120. Herein, the size may include length, width, and/or area. In an embodiment, the signal interconnection structure layer 120 and the power structure layer 130 may be treated as a coreless substrate.

Further, with reference to FIG. 1G, in this embodiment, the power structure layer 130 further includes a deep trench capacitor (DTC) 131 and an integrated voltage regulator (IVR) 133 disposed cavities formed in the same dielectric layer 134. In an embodiment, the deep trench capacitor 131 and the integrated voltage regulator 133 are electrically connected to the patterned circuit layers 122 of the signal interconnection structure layer 120 directly, but the disclosure is not limited thereto.

After that, with reference to FIG. 1G and FIG. 1H together, the carrier 10 is removed, and the active surfaces A of the embedded components 115 and the second surface 113 of the embedded component circuit structure layer 110 are exposed.

Finally, with reference to FIG. 1H, an electronic component layer 140 is disposed on the second surface 113 of the embedded component circuit structure layer 110. The electronic component layer 140 includes a plurality of electronic components 142, 144, 146, and 148 and is electrically connected to the embedded component circuit structure layer 110 through a build-up structure layer 160. The build-up structure layer 160 includes a conductive structure 162 and a dielectric layer 164. The conductive structure 162 penetrates the dielectric layer 164 and is electrically connected to the electronic components 142, 144, 146, and 148, the embedded components 115 of the embedded component circuit structure layer 110, and the metal pillars 112, so high-density interconnection is thereby achieved. In particular, in this embodiment, the coefficient of thermal expansion of the signal interconnection structure layer 120 is higher than the coefficient of thermal expansion of the electronic component layer 140 and the coefficient of thermal expansion of the power structure layer 130, and the coefficients of thermal expansion of the latter two are similar. In this way, a stable balance effect is kept during temperature changes and the board warping is effectively reduced.

In addition, with reference to FIG. 1H, a stabilizing ring 150 is formed on the second surface 113 of the embedded component circuit structure layer 110. The stabilizing ring 150 surrounds the electronic components 142, 144, 146, and 148. In an embodiment, a material of the stabilizing ring 150 may be, for example, stainless steel, but the disclosure is not limited thereto. In an embodiment, a solder ball electrically connected to the outside may be formed on the solder-mask layer 138 of the power structure layer 130, but the disclosure is not limited thereto. At this point, the manufacturing of a package structure 100 is completed.

With reference to FIG. 1H again, structurally, the package structure 100 includes the embedded component circuit structure layer 110, the signal interconnection structure layer 120, the power structure layer 130, and one electronic component layer 140. The embedded component circuit structure layer 110 includes the embedded components 115 and has the first surface 111 and the second surface 113 opposite to each other. The signal interconnection structure layer 120 is disposed on the first surface 111 of the embedded component circuit structure layer 110 and is electrically connected to the embedded component circuit structure layer 110. The power structure layer 130 is disposed on and electrically connected to the signal interconnection structure layer 120. The electronic component layer 140 includes the plurality of electronic components 142, 144, 146, and 148, is disposed on the second surface 113 of the embedded component circuit structure layer 110, and is electrically connected to the embedded component circuit structure layer 110. The coefficient of thermal expansion of the signal interconnection structure layer 120 is higher than the coefficient of thermal expansion of the electronic component layer 140 and the coefficient of thermal expansion of the power structure layer 130.

In an embodiment, the embedded components 115 are, for example, embedded multi-die interconnect bridge (EMIB) chips and may be electrically connected to the electronic components 142, 144, 146, and 148 through the conductive structure 162 of the build-up structure layer 160, so a high-density interconnection is thereby achieved. In an embodiment, the electronic components 142 and 144 may be, for example, artificial intelligence super chips, the electronic component 146 may be, for example, a passive component, and the electronic component 146 may be, for example, an optical co-package, but the disclosure is not limited thereto. Further, in this embodiment, the power structure layer 130 further includes the deep trench capacitor 131 and the integrated voltage regulator 133 embedded therein. In addition, the package structure 100 further includes the stabilizing ring 150 disposed on the second surface 113 of the embedded component circuit structure layer 110 and surrounds the electronic components 142, 144, 146, and 148.

In view of the foregoing, in the package structure of the disclosure, the coefficient of thermal expansion of the signal interconnection structure layer located between the embedded component circuit structure layer and the power structure layer is higher than the coefficient of thermal expansion of the electronic component layer and the coefficient of thermal expansion of the power structure layer, and the coefficients of thermal expansion of the latter two are similar. In this way, a stable balance effect is kept during temperature changes and the package structure warpage is effectively reduced, so the structural stability of the package structure of the disclosure is improved. In addition, compared to the related art in which a core interconnect substrate embedded with an embedded multi-die interconnect bridge chip is used, in the disclosure, in the manufacturing of the coreless embedded component circuit structure layer, the signal interconnection structure layer, and the power structure layer, the total substrate thickness is reduced and the production costs may be also reduced.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A package structure, comprising:
an embedded component circuit structure layer comprising at least one embedded component and having a first surface and a second surface opposite to each other;
a signal interconnection structure layer disposed on the first surface of the embedded component circuit structure layer and electrically connected to the embedded component circuit structure layer;
a power structure layer disposed on and electrically connected to the signal interconnection structure layer; and
an electronic component layer comprising a plurality of electronic components, disposed on the second surface of the embedded component circuit structure layer, and electrically connected to the embedded component circuit structure layer, wherein a coefficient of thermal expansion of the signal interconnection structure layer is higher than a coefficient of thermal expansion of the electronic component layer and a coefficient of thermal expansion of the power structure layer, and the coefficients of thermal expansion of the latter two are similar.

2. The package structure according to claim 1, wherein the embedded component circuit structure layer further comprises:
a plurality of metal pillars;
a dielectric layer having the first surface and the second surface and covering the metal pillars and the at least one embedded component, wherein the second surface of the dielectric layer is aligned with at least one active surface of the at least one embedded component and a top surface of each of the metal pillars;
a plurality of conductive vias extending from the first surface of the dielectric layer and connected to the metal pillars; and
a patterned circuit layer disposed on the first surface of the dielectric layer and electrically connected to the conductive vias.

3. The package structure according to claim 2, wherein a thickness of the dielectric layer is between 75 micrometers and 300 micrometers, and a material of the dielectric layer comprises an epoxy molding compound or an ajinomoto build-up film.

4. The package structure according to claim 1, wherein the signal interconnection structure layer comprises a plurality of dielectric layers, a plurality of patterned circuit layers, and a plurality of conductive blind holes, the dielectric layers and the patterned circuit layers are arranged in an alternating manner, and the conductive blind holes are electrically connected to two adjacent patterned circuit layers.

5. The package structure according to claim 1, wherein the power structure layer is a power plane without traces but contains one or a plurality of different power segments on a same plane and has a plurality of copper layers, a plurality of dielectric layers, a plurality of vias, and a solder-mask layer, the vias penetrate the dielectric layers and are electrically connected to the signal interconnection structure layer.

6. The package structure according to claim 5, wherein the power structure layer further comprises:
a deep trench capacitor and an integrated voltage regulator disposed in at least one of the dielectric layers.

7. The package structure according to claim 1, wherein the electronic components comprise a co-packaged optics, at least one artificial intelligence super chip, at least one passive component, or a combination of the foregoing.

8. The package structure according to claim 1, wherein the at least one embedded component comprises an embedded multi-die interconnect bridge chip.

9. The package structure according to claim 1, further comprising:
a stabilizing ring disposed on the second surface of the embedded component circuit structure layer and surrounding the electronic components.

10. A manufacturing method of a package structure, comprising:
providing a carrier comprising a base, a stainless steel layer, and a metal layer, wherein the stainless steel layer is formed on the base and conformally covers the base, and the metal layer is formed on the stainless steel layer and conformally covers the stainless steel layer;
forming an embedded component circuit structure layer on the carrier, wherein the embedded component circuit structure layer comprises one dielectric layer and at least one embedded component, and at least one active surface of the at least one embedded component contacts the carrier;
forming a signal interconnection structure layer on a first surface of the embedded component circuit structure layer, wherein the signal interconnection structure layer and the embedded component circuit structure layer are electrically connected;
forming a power structure layer on the signal interconnection structure layer, wherein the power structure layer and the signal interconnection structure layer are electrically connected;
removing the carrier and exposing the at least one active surface of the at least one embedded component and a second surface of the embedded component circuit structure layer; and
arranging an electronic component layer comprising a plurality of electronic components on the second surface of the embedded component circuit structure layer, wherein the electronic components and the embedded component circuit structure layer are electrically connected, and a coefficient of thermal expansion of the signal interconnection structure layer is higher than a coefficient of thermal expansion of the electronic component layer and a coefficient of thermal expansion of the power structure layer.
